(19) United States
(12) Patent Application Publication
(10) Pub. No.: US 2016/0118987 A1
(43) Pub. Date: Apr. 28, 2016

(54) Level Shifter With Low Static Power Dissipation

(71) Applicant: Lattice Semiconductor Corporation, Hillsboro, OR (US)

(72) Inventors: Vinh Ho, Milpitas, CA (US); Yaqing Zhou, Santa Clara, CA (US); Jianguo Yao, Fremont, CA (US)

(21) Appl. No.: 14/525,240

(22) Filed: Oct. 28, 2014

(51) Int. Cl. H03K 19/0185

(52) U.S. Cl. CPC H03K 19/018585

(57) ABSTRACT

In one embodiment, a level shifter has a cascade voltage-switching logic (CVSL) structure having two pull-up networks connected in a positive feedback arrangement, each pull-up network connected in series with a corresponding pull-down network. The effective transistor sizes of the two pull-up networks are different such that, at power on, if a level-shifter node connected to an output inverter initially has an in-between voltage level (e.g., at or near the midpoint between the output voltage-domain power-supply voltage and ground), the node voltage will quickly be driven either high or low (depending on the level-shifter design and other initial conditions), thereby reducing leakage current through the output inverter that could otherwise be maintained if the pull-up networks had the same effective transistor size. In addition, one of the pull-down networks has an additional pull-down transistor to accelerate node-voltage driving away from the midpoint to ensure proper operation of the level shifter.

### BACKGROUND

1. Field of the Invention

The present invention relates to electronics and, more specifically but not exclusively, to level shifters.

2. Description of the Related Art

This section introduces aspects that may help facilitate a better understanding of the invention. Accordingly, the statements of this section are to be read in this light and are not to be understood as admissions about what is prior art or what is not prior art.

FIG. 1 shows a schematic circuit diagram of a prior-art level shifter 100 having a conventional cascade voltage-switching logic (CVSL) structure that converts an input signal in in an input voltage domain defined by input power supply voltage vccq1 into an output signal out in an output voltage domain defined by output power supply voltage vccq2, where vccq2 is different from vccq1.

When input signal in is low (e.g., ground), inverted signal in2b is high (e.g., vccq1), and double-inverted signal in2bb is low. As such, n-type transistor (e.g., NMOS) n1 will be on, and n-type transistor n2 will be off. In that case, node nd1 will be driven towards ground through n1, which turns on p-type transistor (e.g., PMOS) p2, which in turn drives node nd2 towards vccq2, which ensures that p-type transistor p1 is off. With node nd1 driven low, output inverters inv3 and inv4 will operate to drive output signal out low.

When input signal in is high (e.g., vccq1), inverted signal in2b is low, and double-inverted signal in2bb is high. As such, transistor n1 will be off, and transistor n2 will be on. In that case, node nd2 will be driven towards ground through n2, which turns on transistor p1, which in turn drives node nd1 towards vccq2, which ensures that transistor p2 is off. With node nd1 driven towards vccq2, inverters inv3 and inv4 will drive output signal out towards vccq2.

Thus, when input signal in is low in the vccq1 voltage domain, the output signal out is low in the vccq2 voltage domain, and, when input signal in is high in the vccq1 voltage domain, the output signal out is high in the vccq2 voltage domain. In this way, level shifter 100 converts input signal in in the vccq1 voltage domain into output signal out in the vccq2 voltage domain.

Transistors p1 and p2 are considered to be part of two pull-up networks connected in a positive feedback arrangement, while transistors n1 and n2 are considered to be part of two pull-down networks, wherein the pull-down network of n1 is connected in series with the pull-up network of p1, and the pull-down network of n2 is connected in series with the pull-up network of p2. When level shifter 100 is operating properly, when input signal in is low, the pull-down network of n1 and the pull-up network of p2 are on, and the pull-down network of n2 and the pull-up network of p1 are off, and, when input signal in is high, the pull-down network of n1 and the pull-up network of p2 are off, and the pull-down network of n2 and the pull-up network of p1 are on.

When an integrated circuit containing level shifter 100 is initially powered on, it is possible for the power supply voltages vccq1 and vccq2 to rise at different rates and at different times towards their desired (i.e., normal) operating levels. In some circumstances, this can lead to certain undesirable operations of level shifter 100. In particular, undesirable operations can occur when vccq2 approaches its normal operating level faster than vccq1 approaches its normal operating level.

Assume the extreme situation in which vccq2 has reached its normal operating level, while vccq1 is still at ground (e.g., 0 volts). In that case, inverters inv1 and inv2 will not be operating. With input signal in low, both inverted signals in2b and in2bb will also be low, and transistors n1 and n2 will both be off. As a result, the voltages at nodes nd1 and nd2 will be indeterminate (i.e., the voltages could independently be high, low, or in between). If the voltages at both nodes nd1 and nd2 are between vccq2 and ground (e.g., about ½ of vccq2), then those voltages could stay at those in-between levels for an extended period of time, during which inverter inv3 might not operate properly and could result in an undesirably large leakage current for an undesirable length of time from vccq2 to ground through inverter inv3.

### BRIEF DESCRIPTION OF THE DRAWINGS

Other embodiments of the invention will become more fully apparent from the following detailed description, the appended claims, and the accompanying drawings in which like reference numerals identify similar or identical elements.

FIG. 1 shows a schematic circuit diagram of a prior-art level shifter; and

FIGS. 2-4 show schematic circuit diagrams of level shifters according to different embodiments of the disclosure.

### DETAILED DESCRIPTION

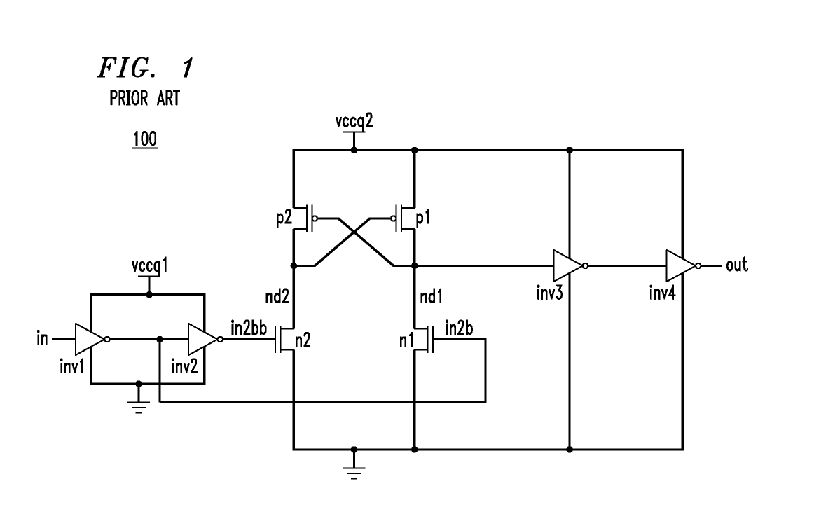

In a conventional level shifter, such as level shifter 100 of FIG. 1, the sizes of the transistors in the two pull-down networks are the same (i.e., n1 equals n2), and the sizes of the transistors in the two pull-up networks are the same (i.e., p1 equals p2). According to certain embodiments of the disclosure, however, the effective sizes of the two pull-up networks are different.

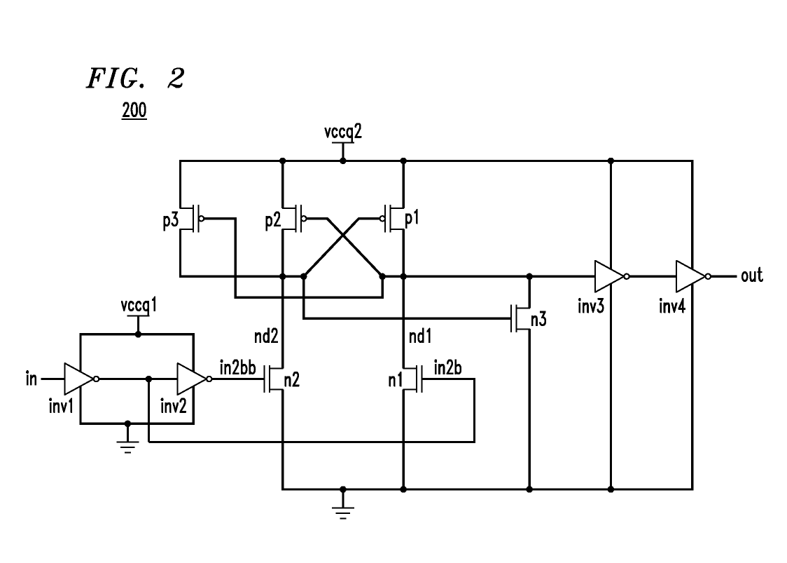

FIG. 2 shows a schematic circuit diagram of a level shifter 200 according to one embodiment of the disclosure. Like level shifter 100 of FIG. 1, level shifter 200 converts an input signal in in an input voltage domain defined by input power supply voltage vccq1 (e.g., 0.6V in one exemplary embodiment) into an output signal out in an output voltage domain defined by output power supply voltage vccq2 (e.g., 0.8V in the one exemplary embodiment), where vccq2 is different from vccq1.

Level shifter 200 is identical to level shifter 100 of FIG. 1, except for the inclusion of p-type transistor p3 and n-type transistor n3 in level shifter 200. As shown in FIG. 2, transistor p3 is connected in parallel with transistor p2 with the source, drain, and gate of p3 connected to the same respective nodes as the source, drain, and gate of p2. Since transistors p1 and p2 have the same size, the addition of p3 makes the effective size of the pull-up network of transistors p2 and p3 larger than the effective size of the pull-up network of transistor p1.

When power-supply voltages vccq1 and vccq2 are at their respective normal operating voltage levels, level shifter 200 will operate as described previously for the normal operations of level shifter 100 of FIG. 1. If, however, for example, during power up, vccq2 approaches its normal voltage level sooner than vccq1 approaches its normal voltage level, level shifter 200 will not suffer the same undesirable operations as level shifter 100.

In particular, assume again the extreme situation in which vccq2 has reached its normal operating level, while vccq1 is still at ground. In that case, inverters inv1 and inv2 will again not be operating, and, with input signal in low, both inverted signals in2b and in2bb will also be low, and transistors n1 and n2 will both be off. Here, too, as a result, the voltages at nodes nd1 and nd2 will be initially indeterminate (i.e., the voltages could independently be high (e.g., at or near vccq2), low (e.g., at or near ground), or in between (e.g., at or near ½ of vccq2). There are nine different possible initial, power-up situations corresponding to the nine different possible combinations of (i) nd1 being high, in between, or low and (ii) nd2 being independently high, in between, or low.

If nd1 and nd2 are both initially high, then p1, p2, and p3 will be off, and n-type transistor n3 will turn on, which will drive nd1 low, which will turn on p2 and p3, thereby ensuring that nd2 stays high, that p1 stays off. With nd1 low, inverters inv3 and inv4 will both operate properly without any unreasonably high and lengthy leakage currents.

If nd1 is initially high, but nd2 is initially in between, then p2 and p3 will be off, but p1 could be partially on. With p1 partially on, nd1 will stay high, thereby keeping p2 and p3 off. With nd1 high, inverters inv3 and inv4 will both operate properly without any unreasonably high and lengthy leakage currents.

If nd1 is initially high, but nd2 is initially low, then p2 and p3 will be off, but p1 will be on. With p1 on, nd1 will stay high, thereby keeping p2 and p3 off. With nd1 high, inverters inv3 and inv4 will both operate properly without any unreasonably high and lengthy leakage currents.

If nd1 is initially in between, but nd2 is initially high, then p2 and p3 could be partially on, while p1 is off. With p2 and p3 partially on, nd2 will stay high, and n3 will turn on, which will drive nd1 from in between to low, which will turn p2 and p3 fully on, thereby ensuring that nd2 stays high, that p1 stays off, and that nd1 stays low. With nd1 low, inverters inv3 and inv4 will both operate properly without any unreasonably high and lengthy leakage currents.

If both nd1 and nd2 are initially in between, then p1, p2, and p3 could all be partially on. Since the pull-up network of p2 and p3 is larger than the pull-up network of p1, nd2 will be driven high through both p2 and p3 faster than nd1 will be driven high through smaller p1. As such, n3 will begin to turn on, thereby driving nd1 low and turning p2 and p3 fully on, which drives nd2 high even faster, which turns p1 off and n3 fully on, which drives nd1 low even faster. With nd1 low, inverters inv3 and inv4 will both operate properly without any unreasonably high and lengthy leakage currents.

If nd1 is initially in between, but nd2 is initially low, then p1 will be on. With p1 on, nd1 will be driven high, which ensures that p2 and p3 will be off. With nd1 high, inverters inv3 and inv4 will both operate properly without any unreasonably high and lengthy leakage currents.

If nd1 is initially low, but nd2 is initially high, then p2 and p3 will be on and p1 will be off. With p2 and p3 on, nd2 will be driven high, thereby ensuring that p1 will stay off and turning on n3, which ensures that p2 and p3 stay on and nd1 stays low. With nd1 low, inverters inv3 and inv4 will both operate properly without any unreasonably high and lengthy leakage currents.

If nd1 is initially low, but nd2 is initially in between, then p2 and p3 will be on, which will drive nd2 high, thereby ensuring that p1 is off. With nd2 high, n3 will turn on, thereby ensuring that nd1 stays low and that p2 and p3 stay on. With nd1 low, inverters inv3 and inv4 will both operate properly without any unreasonably high and lengthy leakage currents.

If nd1 and nd2 are both initially low, then p1, p2, and p3 will all be initially on. Because the pull-up network of p2 and p3 is larger than the pull-up network of p1, nd2 will be driven high faster than nd1 is driven high. As a result, n3 will turn on, thereby driving nd1 low, thereby ensuring that p2 and p3 will stay on and nd2 stays high, turning off p1. With nd1 low, inverters inv3 and inv4 will both operate properly without any unreasonably high and lengthy leakage currents.

Note that, if, during power up, vccq1 approaches its normal voltage level sooner than vccq2 approaches its normal voltage level, level shifter 200 will also ensure that node nd1 is quickly driven either high or low. Assume, here, the extreme situation that vccq1 is at its normal voltage level, while vccq2 is at ground.

In that case, if input signal in is low, then in2b will be high and in2bb will be low, and n1 will be on and n2 will be off. With n1 on, node nd1 will be driven low, and inverters inv3 and inv4 will both operate properly without any unreasonably high and lengthy leakage currents.

Similarly, if input signal in is high, then in2b will be low and in2bb will be high, and n1 will be off and n2 will be on. With n2 on, node nd2 will be driven low, which will keep n3 off and eventually turn p1 on, thereby driving node nd1 high, such that inverters inv3 and inv4 will both operate properly without any unreasonably high and lengthy leakage currents.

In this way, the inclusion of transistors p3 and n3 in level shifter 200 ensures that the voltage at node nd1 will (i) stay low if it is initially low and (ii) be driven quickly to one of high and low if it is initially in between or high, depending on the initial voltage at node nd2. In particular, the inclusion of transistor p3, which results in the pull-up network of p2 and p3 being larger than the pull-up network of p1, ensures that the voltage at node nd1 will not stay in between ground and vccq2 for very long, thereby avoiding undesirably high and lengthy leakage current through inverter inv3. Transistor n3 can be considered to be part of the pull-down network of transistor n1, since both n1 and n3 are connected to pull down node nd1.

Adding a second transistor (i.e., p3) to the pull-up network of p2 is one way to create a level shifter in which the pull-up network of p2 is larger than the pull-up network of p1. Another way to effectively achieve the same result is to replace transistor p2, which has the same size as transistor p1, with a larger transistor.

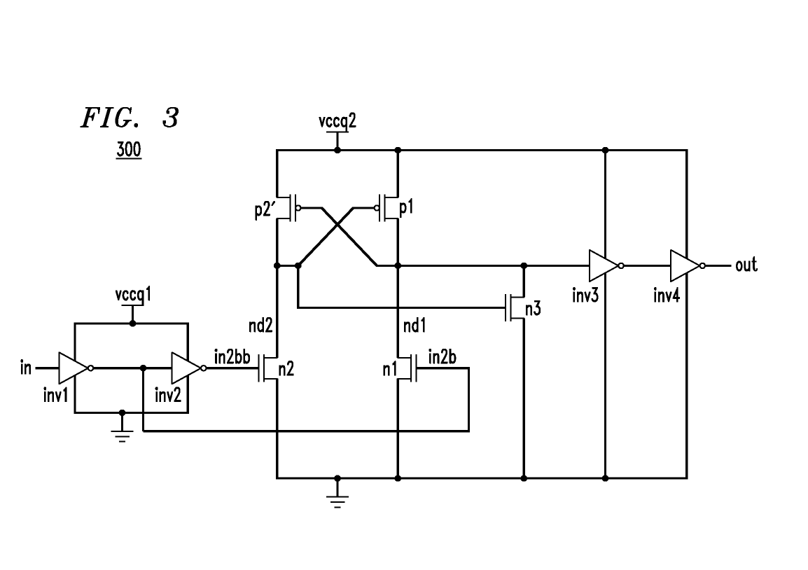

FIG. 3 shows a schematic circuit diagram of a level shifter 300 according to another embodiment of the disclosure. Like level shifter 200 of FIG. 2, level shifter 300 converts an input signal in in the vccq1 voltage domain into an output signal out in the vccq2 voltage domain, where vccq2 is different from vccq1. Level shifter 300 is identical to level shifter 200, except that transistors p2 and p3 of FIG. 2 are replaced by a single transistor p2′ having a size equivalent to the effective combination of transistors p2 and p3. Note that transistor n3 of FIG. 3 is identical to transistor n3 of FIG. 2. As such, level shifter 300 operates in a substantially identical manner as level shifter 200.

One goal of the present disclosure is to provide a level shifter that ensures that, when node nd1 happens to be at an in-between voltage level at or soon after power on, it does not stay at that in-between voltage level for very long, but is instead quickly driven either high or low to avoid unreasonably high and lengthy leakage currents through the level shifter's output inverters. Level shifters 200 and 300 of FIGS. 2 and 3 achieve that goal by having the pull-up network of transistor p1 be smaller than the level-shifter's other pull-up network. Another way to achieve that same goal is to implement level shifters in which the pull-up network of transistor p1 is larger than the level-shifter's other pull-up network.

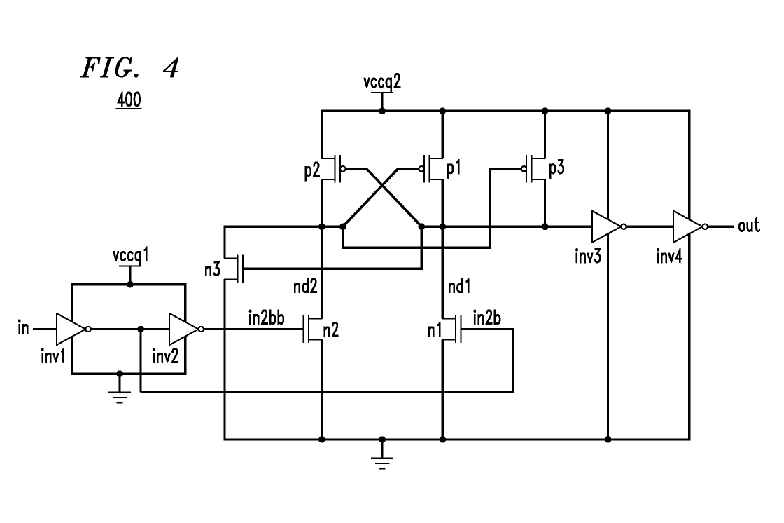

FIG. 4 shows a schematic circuit diagram of a level shifter 400 according to yet another embodiment of the disclosure. Like level shifters 200 and 300 of FIGS. 2 and 3, level shifter 400 converts an input signal in in the vccq1 voltage domain into an output signal out in the vccq2 voltage domain, where vccq2 is different from vccq1. Level shifter 400 is identical to level shifter 200, except that (i) the extra p-type transistor p3 is added to the pull-up network of transistor p1 (instead of to the pull-up network of transistor p2) and (ii) the extra n-type transistor n3 is configured such that its source is connected to node nd1 and its gate is connected to node nd2 (instead of the other way around as with transistor n3 of FIG. 2).

Level shifter 400 will operate in a similar manner as level shifters 200 and 300, except that, because the pull-up network of p1 (and p3) is larger than the pull-up network of p2, there are certain situations in which node nd1 will be driven high instead of low as in FIGS. 2 and 3. Significantly, however, as with the other two level shifters, when node nd1 happens to be at an in-between voltage level at or soon after power on, it does not stay at that in-between voltage level for very long, but is instead quickly driven either high or low to avoid unreasonably high and lengthy leakage currents through the level shifter's output inverters.

Although not shown explicitly in a figure, those skilled in the art will understand that, in another embodiment, transistors p1 and p3 of FIG. 4 can be replaced by a single, equivalent transistor p1′ that is larger than the size of transistor p2. Such alternative embodiment will operate identically to level shifter 400.

Level shifters of the present disclosure can be implemented for applications in which the output voltage domain is smaller than the input voltage domain (i.e., vccq2<vccq1) as well as applications in which the output voltage domain is greater than the input voltage domain (i.e., vccq2>vccq1).

Level shifters of the present disclosure can be implemented in any suitable integrated circuit, such as (without limitation) field-programmable gate arrays (FPGAs), application-specific integrated circuits (ASICs), and general-purpose microprocessors.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Also, for purposes of this disclosure, it is understood that all gates are powered from a fixed-voltage power domain (or domains) and ground unless shown otherwise. Accordingly, all digital signals generally have voltages that range from approximately ground potential to that of one of the power domains and transition (slew) quickly. However and unless stated otherwise, ground may be considered a power source having a voltage of approximately zero volts, and a power source having any desired voltage may be substituted for ground. Therefore, all gates may be powered by at least two power sources, with the attendant digital signals therefrom having voltages that range between the approximate voltages of the power sources.

Signals and corresponding nodes, ports, or paths may be referred to by the same name and are interchangeable for purposes here.

Transistors are typically shown as single devices for illustrative purposes. However, it is understood by those with skill in the art that transistors will have various sizes (e.g., gate width and length) and characteristics (e.g., threshold voltage, gain, etc.) and may consist of multiple transistors coupled in parallel to get desired electrical characteristics from the combination. Further, the illustrated transistors may be composite transistors.

As used in this specification and claims, the term “channel node” refers generically to either the source or drain of a metal-oxide semiconductor (MOS) transistor device (also referred to as a MOSFET), the term “channel” refers to the path through the device between the source and the drain, and the term “control node” refers generically to the gate of the MOSFET. Similarly, as used in the claims, the terms “source,” “drain,” and “gate” should be understood to refer either to the source, drain, and gate of a MOSFET or to the emitter, collector, and base of a bi-polar device when an embodiment of the invention is implemented using bi-polar transistor technology.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

What is claimed is:

1. An integrated circuit comprising a level shifter configured to convert an input signal (e.g., in) in a first voltage domain defined by a first power-supply voltage (e.g., vccq1) into an output signal (e.g., out) in a second voltage domain defined by a second power-supply voltage (e.g., vccq2) different from the first power-supply voltage, the level shifter comprising:
a first pull-up network (e.g., p1);
a second pull-up network (e.g., p2+p3) connected to the first pull-up network in a positive feedback arrangement;
a first pull-down network (e.g., n1) connected in series with the first pull-up network;
a second pull-down network (e.g., n2) connected in series with the second pull-up network; and
at least one output inverter (e.g., inv3) having an input connected to a first node (e.g., nd1) between the first pull-up network and the first pull-down network, wherein:
the first pull-up network has a first effective transistor size;
the second pull-up network has a second effective transistor size different from the first effective transistor size, such that the different effective transistor sizes between the first and second pull-up networks inhibits the first node from maintaining an in-between voltage level between ground and the second power-supply voltage in order to reduce leakage current through the at least one output inverter.

2. The invention of claim 1, wherein one of the first and second pull-down networks has an additional pull-down transistor (e.g., n3) whose (i) channel is connected between ground and either (a) the first node or (b) a second node (e.g., nd2) between the second pull-up network and the second pull-down network and whose (ii) gate is connected to the other of the first and second nodes.

3. The invention of claim 2, wherein:
the first pull-up network comprises a first p-type transistor (e.g., p1);
the second pull-up network comprises a second p-type transistor (e.g., p2);
the first pull-down network comprises a first n-type transistor (e.g., n1); and
the second pull-down network comprises a second n-type transistor (e.g., n2).

4. The invention of claim 3, wherein the first pull-down network comprises the additional pull-down transistor (e.g., n3 of FIGS. 2 and 3) whose (i) channel is connected between ground and the first node and whose (ii) gate is connected to the second node.

5. The invention of claim 4, wherein the second pull-up network further comprises a third p-type transistor (e.g., p3 of FIG. 2) connected in parallel with the second p-type transistor.

6. The invention of claim 4, wherein the second p-type transistor (e.g., p2′ of FIG. 3) is larger than the first p-type transistor.

7. The invention of claim 3, wherein the second pull-down network comprises the additional transistor (e.g., n3 of FIG. 4) whose (i) channel is connected between ground and the second node and whose (ii) gate is connected to the first node.

8. The invention of claim 7, wherein the first pull-up network further comprises a third p-type transistor (e.g., p3 of FIG. 4) connected in parallel with the first p-type transistor.

9. The invention of claim 7, wherein the first p-type transistor (e.g., p1′) is larger than the second p-type transistor.

10. The invention of claim 1, wherein the integrated circuit is an FPGA.
